(19) United States
(12) Patent Application Publication
(10) Pub. No.: US 2002/0162673 A1
(43) Pub. Date: Nov. 7, 2002

(54) Use of doped synthetic polymer materials for packaging of power electric assemblies for a liquid cooled module

(76) Inventors: Derrick E. Cook, Saline, MI (US); Peter A. Hatch, Dearborn Heights, MI (US); Paul William Keberly, Canton, MI (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/848,482

(22) Filed: May 3, 2001

(51) Int. Cl. H05K 9/00

(52) U.S. Cl. 174/35 MS

(57) ABSTRACT

The invention is a doped synthetic polymer materials for packaging of power electric assemblies. The polymer provides electromagnetic interference (EMI) shielding using such materials as nickel, carbon fiber, aluminum or other such characteristic elements. The invention provides structural integrity for power electronic packaging, while reducing cost, size, weight and design flexibility over the prior art. The illustrated embodiment is a liquid cooled turbulent flow power electronic assembly.

### BACKGROUND OF THE INVENTION

1. Field of the Invention

The present invention generally relates to a power electronic assembly enclosure and, more particularly, to an improved enclosure using doped polymer materials for packaging of power electronic assemblies for a liquid cooled module.

2. Discussion of the Prior Art

Electronic devices are becoming more prevalent and more complex. These devices are an integral part of virtually every home and business. Even traditionally mechanical devices, such as automobiles, are incorporating ever larger and more complex electronic elements.

Electronic devices generate and are penetrated by electromagnetic radiation or interference (EMI). The frequencies and amplitudes of the EMI vary depending on the device. In most cases, such EMI is an unwanted by-product of electronic activity. Some EMI interferes with certain parts of the same equipment or with other electronic units located near the equipment.

It is known in the prior art that use of a metallic or electrically conductive enveloping enclosure prevents the transmission of or interference from EMI within a protected space. This is sometimes called an electromagnetic shield. In some cases, this shield is soldered to the electric device. This application often requires attachment points on the circuit and is difficult to remove once installed. Alternatively, when a large area requires protecting, the shield could be cast to accommodate the entire electric circuit or device. These solid, continuous metal enclosures provide a good barrier to EMI. Unfortunately, these enclosures are often costly, heavy, and cumbersome. Thus, the enclosures may interfere with design considerations.

Issues of electromagnetic shield cost, weight, size, and design are also addressed to some extent in the prior art. For example, U.S. Pat. No. 4,890,199 (Beutler) provides a space saving electromagnetic shield. The shield uses a conductive material having opposing cantilever spring fingers that can be easily removed. This permits assembly by using automatic manufacturing processes. This invention is particularly adapted to miniature electronic equipment such as portable telephones because an object of the invention was to use as little shielding space as possible.

U.S. Pat. No. 5,353,201 (Maeda) provides an EMI shield device that can attach to a printed circuit board having electrical components. The shield body is made of a material of desired magnetic permeability. The invention uses a plurality of legs that penetrate a slit on the printed circuit board. Its construction, therefore, does not require a large number of sites to be connected by soldering or welding. U.S. Pat. No. 5,684,340 (Soler, et al.) provides an arrangement of components for EMI shield that allows signal or power conductors to pass through the enclosure without compromising the effectiveness of the shield. The invention envisages conducting zones, arranged on the faces of the printed circuit board, interacting with a conductive joint that provides good electrical contact with the conductive protective enclosure. An object of the Soler et al. invention is the use of standard, cheap and easily assembled parts.

EMI shields composed of polymers are also known in the prior art. U.S. Pat. No. 5,571,991 (Highum et al.) discusses a shield for housing electronic components providing a barrier to electromagnetic radiation. The enclosure has three layers. The outer and inner surface are of a polymeric base material in which is suspended an electrically conductive fill material, giving the layers high electrical conductivity. The middle layer is a polymeric base material suspended with fill material having high magnetic permeability. The resultant molded structure can be made inexpensively in a single co-injection molding operation.

Prior art plastic EMI shields with a metal inner surface to prevent EMI are also known in the prior art. The metal film is prepared by using surface treatment techniques such as plating, coating, depositing and flame coating. For example, U.S. Pat. No. 5,841,067 (Nakamura et al.) provides a housing sheet molded from magnetic material containing a specific resin composition with the interior surface lined with a conductive material. Unfortunately, in a high-density compact area, such as small electronic equipment, this can result in short circuits because of the small distance between components of the circuit and the metal film.

U.S. Pat. No. 5,867,370 (Masuda) discloses a plastic EMI shield using a conductive resin covered by a nonconductive resin. Other plastic shielding devices have developed. U.S. Pat. No. 5,137,782 (Adriaenson et al.) provides a granular composite having metal fibers for incorporation into resins. Various EMI shielding characteristics are obtained using different processing conditions. See also, generally U.S. Pat. No. 5,827,997 (Chung et al.).

The prior art power electronic packaging is dominated by metallic enclosures that provide mechanical integrity, environmental sealing, and EMI shielding. Metallic based enclosures are typically costly, heavy and do not offer a high degree of freedom with regard to packaging form. Other solutions in the prior art attempt to solve these problems using polymer housings combined with metal films or metal composites. Although lightweight, these shields add considerable cost.

A further problem is that the reliability of electronic components is known to decrease with increasing temperatures. It has been generally found that the life span of some electronic components is directly related to the temperature at which it operates. In order to keep the component cool, a heat sink is used. A heat sink often has a large heat conducting plate to which components are attached in heat-conducting relation. One heat-conducting plate that is often used is called a coldplate. The coldplate is cooled by applying a cooling means, such as a liquid coolant, to one side of the cooling plate while a component to be cooled is attached to the other side of the coldplate, thereby cooling that component.

A disadvantage with prior art coldplates is that heat transfer from a power electronic device is diminished to some degree because the heat must travel through the base plate of the housing in which the device is enclosed and across the interface between the base plate and the coldplate before it reaches the coldplate. Localized hot spots can occur in the baseplate and coldplate, and the power electronic device is subject to higher operating temperatures. To mitigate this effect, larger and thicker base plates are often used to better distribute heat across the base plate-coldplate interface. The additional weight resulting from increased base plate and coldplate thickness is often undesirable, especially in automobile applications.

U.S. Pat. No. 4,531,146 (Cutchaw) provides an apparatus for cooling high-density integrated circuit packages that include a specifically configured heat exchanger the circuit package within a base means and carries heat away from the package by means of a coolant that is passed through the heat exchanger.

U.S. Pat. No. 5,159,529 (Lovgren et al.) shows a coolant management system for cooling electrical components. The management system has a first heat transfer plate, preferably made of copper, for mounting to electronic components to be cooled. When the first heat transfer plate is attached to the coolant management means, preferably made of a plastic material, a coolant cavity is formed. A second heat transfer plate, preferably also made of copper, is also attached to the coolant management means, creating a second coolant cavity. By restricting the use of materials with a high thermal conductivity to only the areas requiring thermal conduction, this invention provided for a coolant management system that was lightweight and smaller in size.

U.S. Pat. No. 5,453,911 (Wolgemuth et al.) relates to a power electronic device cooled by directly impinging a cooling fluid against the base of the device. The cooling fluid flows to and from the device through the plate to which the device is mounted. In addition, the coldplate utilizes nozzles and deflectors that are able to selectively enhance the cooling capability by minimizing the boundary layer at the base plate of the components.

U.S. Pat. No. 5,841,634 (Visser) is for a liquid-cooled heat sink for a semiconductor device that includes a baffle for directing the cooling fluid in both a series and parallel direction. This remedies the problem of stagnation of the coolant liquid at the heat sink/coolant interface.

U.S. Pat. No. 6,016,007 (Sanger et al.) relates to a cooling arrangement for high-power semiconductor devices. The semiconductor device is mounted to one side of a thermally and electrically conductive carrier member having a coefficient of thermal expansion that closely matches that of the semiconductor device. A cooling assembly is thermally coupled to a second side of the carrier and includes dielectric cooling liquid flowing through the heat exchanger.

U.S. Pat. No. 6,052,284 (Suga et al.) provides a printed circuit board equipped with a cooler. The cooler has a sealed case wherein a liquid coolant is passed over the printed circuit board mounted with semiconductor devices of large calorific power. This invention does not involve the immersion of the printed circuit board structure in the coolant and, therefore, is smaller but still efficient.

U.S. Pat. No. 6,055,158 (Pavlovic) discloses a more efficient assembly process for a heat sink. This invention remedies the prior problems created by attaching header connectors to the metallic enclosure box using potting/sealing compounds during a secondary assembly process. The assembly process permits header connectors to be formed as an integral part of a molded plastic frame.

A doped synthetic polymer based liquid cooled coldplate assembly that is cost efficient, provides mechanical integrity, sealing, EMI shielding, and unique assembly options that will lead to a greatly simplified assembly process is needed. Utilizing these qualities for the packaging of power electronic devices specifically for automotive use is also needed.

### SUMMARY OF THE INVENTION

Accordingly, an object of the present invention is to provide a doped synthetic polymer materials for packaging of power electric assemblies for a liquid cooled module.

It is a further object of the present invention to provide a doped synthetic polymer for a liquid cooled module that provides electromagnetic interference (EMI) shielding.

It is a further object of the present invention to provide a doped synthetic polymer for a liquid cooled module that provides electromagnetic interference (EMI) shielding using such materials as nickel, carbon fiber, aluminum or other such characteristic elements.

It is a further object of the present invention to provide a doped synthetic polymer for a liquid cooled module that provides structural integrity for power electronic packaging.

It is a further object of the present invention to provide a doped synthetic polymer for a liquid cooled module that provides reduced cost, size, weight and design flexibility over the prior art.

It is a further object of the present invention to provide a liquid cooled turbulent flow power electronic assembly using a doped synthetic polymer that is cost efficient, provides mechanical integrity, sealing, EMI shielding, and unique assembly options that will lead to a greatly simplified assembly process is needed.

Other objects of the present invention will become more apparent to persons having ordinary skill in the art to which the present invention pertains from the following description taken in conjunction with the accompanying figures.

### BRIEF DESCRIPTION OF THE FIGURES

The foregoing objects, advantages, and features, as well as other objects and advantages, will become apparent with reference to the description and figures below, in which like numerals represent like elements and in which:

FIG. 1 shows an exploded view of the illustrated embodiment.

FIG. 2 shows a top view of a housing of the illustrated embodiment.

FIG. 3 shows a top view of a backplate of the illustrated embodiment.

### DETAILED DESCRIPTION OF THE PREFERRED EMBODIMENT

The present invention provides a unique packaging solution using plastic polymer blends to provide electromagnetic interference (EMI) shielding and structural integrity for a liquid cooled module. The illustrated embodiment provides a doped synthetic polymer for a liquid cooled turbulent flow power electric assembly that provides reduced cost, size, and weight while also offering variable degrees of EMI shielding for the packaging of power electronic modules and associated EMI radiating electronic assemblies.

The advantages of the doped synthetic polymer of the present invention make it especially suited for applications in an automobile although several other applications are possible. Synthetic polymers are very durable and able to withstand the often harsh environmental conditions experienced by an automobile. Injection molding to produce such polymers allows use of inexpensive raw materials while providing great design form flexibility. Design form flexibility is critical to most automotive applications given the often-limited space availability. A doped synthetic polymer can provide EMI shielding and is non-corrosive. And finally, a doped synthetic polymer can reduce labor cost over prior art EMI solutions by having fewer parts to assemble.

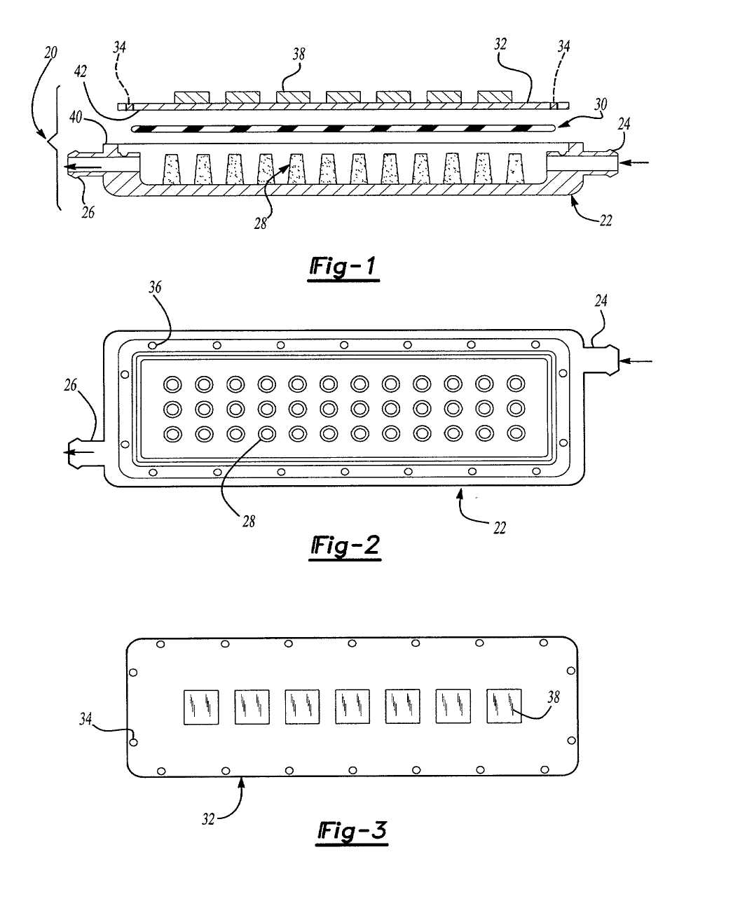

One embodiment of the present invention is illustrated in FIGS. 1, 2 and 3 although several various configurations could be possible to one skilled in the art. In the FIG. 1, an assembly 20 is shown for a liquid cooled module enclosure for an automotive packaging of electronic modules. The assembly has an assembly housing 22 that is a synthetic polymer based material doped with such materials as nickel, carbon fiber, aluminum or other such characteristic elements. These materials combined in various configurations by one skilled in the art provide not only mechanical integrity but also sealing, various EMI shielding and design flexibility. The assembly housing 22 a coolant inlet 24, a coolant outlet 26 to a heat exchanger (not shown), and turbulent flow pins 28. Many other possible means to provide coolant turbulence, such as baffles, are possible and the illustrated embodiment's turbulent flow pins 28 shown in FIGS. 1 and 2 provide just one such possibility. The assembly housing 22 in this embodiment has an open end with a flat edge 40.

The assembly 20 also has an O-ring 30 and a backplate 32. The backplate 32 can be made of aluminum or any other thermal-conductive material and is shown in FIGS. 1 and 3. The backplate 32 can be made of sufficient thickness to allow even distribution of cooling capacity. The backplate 32 has a matching flat edge 42 to receive and seal against housing flat edge 40. The backplate 32 additionally has openings 34 to allow screws or other means of attachment (not shown) to pass through and attach the assembly housing 22 through corresponding housing holes 36. The O-ring 30 provides a watertight seal when the backplate 32 attaches to the assembly housing 22. An alternate embodiment could allow the backplate 32 to be insert molded directly into the assembly housing 22 using a process well known in the prior art.

The backplate 32 also has an attachment means to attach electronic components that need cooling (not shown) using methods well known in the art. For illustrative purposes, FIGS. 1 and 3 show semiconductors 38 attached to the backplate 32. A particular advantage of the present invention is that the synthetic polymer can actually provide insulative properties to the housing so that all heat transfer is concentrated toward the backplate 32. Further, since the backplate 32 allows direct contact to the electronic components and the coolant, the need for a prior art thermal pad is also eliminated. This improves heat transfer efficiency.

The above-described embodiment of the invention is provided purely for purposes of example. Many other variations, modifications, and applications of the invention may be made.

I claim:

1. A synthetic polymer material for packaging power electric assemblies for a liquid cooled module.

2. The synthetic polymer material of claim 1 further comprising a material to provide electromagnetic interference (EMI) shielding.

3. The synthetic polymer material of claim 2 wherein the EMI shielding material is nickel.

4. The synthetic polymer material of claim 2 wherein the EMI shielding material is carbon fiber.

5. The synthetic polymer material of claim 2 wherein the EMI shielding material is aluminum.

6. A liquid cooled turbulent flow power electronic assembly using a doped synthetic polymer comprising:
a housing comprising turbulent flow features, an inlet and outlet for coolant and an open end comprising a flat edge around a perimeter of the open end for receiving an O-ring;
a heat conducting backplate to attach electronic components to be cooled comprising a backplate flat edge to match the housing flat edge to receive and seal against the housing flat edge; and
an attachment means to attach the assembly housing and backplate.

7. The assembly of claim 6 further comprising an O-ring inserted between the backplate and the flat edge of the housing wherein a watertight seal is formed.

8. The assembly of claim 6 wherein the attachment means is by at least one screw.

9. The assembly of claim 6 wherein the attachment means is by insert molding the backplate to the housing.

10. The assembly of claim 6 wherein the backplate is aluminum.

11. The assembly of claim 6 wherein the backplate is of sufficient thickness to allow even distribution of cooling capacity.

12. The assembly of claim 6 wherein the housing provides electromagnetic interference (EMI) shielding.
